(19) United States
(12) Patent Application Publication
(10) Pub. No.: US 2019/0221583 A1
(43) Pub. Date: Jul. 18, 2019

(54) DRIVE DEVICE AND DISPLAY DEVICE

(71) Applicant: HKC CORPORATION LIMITED, Shenzhen, Guangdong (CN)

(72) Inventor: Jianfeng Shan, Shenzhen, Guangdong (CN)

(21) Appl. No.: 16/070,354

(22) PCT Filed: Jan. 26, 2018
(86) PCT No.: PCT/CN2018/074315

§ 371 Date: Jul. 16, 2018

(30) Foreign Application Priority Data
Oct. 25, 2017 (CN) 201711012958.2

(51) Int. Cl. H01L 27/12; G09G 3/36

(52) U.S. Cl. CPC H01L 27/124; G09G 3/3677; G09G 2320/0242; G09G 2300/0447; G09G 2320/028

(57) ABSTRACT

Disclosed is a drive device and a display device. In the drive device, a first substrate row driving circuit is disposed on one side of a scan line array and configured to independently drive first scan lines; while a second substrate row driving circuit is disposed on the other side of the scan line array and configured to independently drive second scan lines. After the first substrate row driving circuit independently drives the first scan lines, the second substrate row driving circuit would then independently drive the second scan lines. Thus when the second substrate row driving circuit is independently driving the second scan lines, a potential difference is generated between a main pixel and a pixel in the display area corresponding to the active switch array.

### TECHNICAL FIELD

This application relates generally to the field of display panels, and more particularly relates to a drive device and a display device.

### BACKGROUND

Currently when a user views a liquid crystal display (LCD) panel of a vertical alignment (VA) type from the side, color shift occurs especially with large-size LCD panels, and the degree of color shift will increase as the side viewing angle increases. In order to reduce the color shift and increase the viewing angle range, each pixel of the display area of the LCD panel is usually divided into a sub-pixel and a main pixel, and a potential difference is generated between the sub-pixel and the main pixel so as to control the tilt angle of the liquid crystal in the liquid crystal display panel to change thus achieving the effect of alleviating the color shift. But in reducing the color shift, the scan line that controls the potential difference to be generated between the sub-pixel and the main pixel suffers a large load.

### SUMMARY

It is therefore a main object of this application to provide a drive device and a display device, which are intended to solve a problem of the large load suffered by the scan line that controls the potential difference to be generated between a sub-pixel and a main pixel.

To achieve the above-described object, this application provides a drive device including:

an active switch array including driving thin film transistors and charge sharing thin film transistors;

a scan line array including first scan lines and second scan lines, where the first scan lines are configured to independently drive the driving thin film transistors while the second scan lines are configured to independently drive the charge sharing thin film transistors;

a substrate row driving circuitry including:

a first substrate row driving circuit disposed on one side of the scan line array and configured to independently drive the first scan lines;

a second substrate row driving circuit disposed on the other side of the scan line array and configured to independently drive the second scan lines.

After the first substrate row driving circuit independently drives the first scan lines, the second substrate row driving circuit may then drive the second scan lines;

When the second substrate row driving circuit is independently driving the second scan lines, a potential difference would generate between the main pixel and the sub-pixel in the display area corresponding to the active switch array.

Optionally, the first substrate row driving circuit may drive the first scan lines to turn on or off in order to control turning on or off of the driving thin film transistors.

Optionally, the second substrate row driving circuit may drive the second scan lines to turn on or off in order to control turning on or off of the charge sharing thin film transistors.

Optionally, each of the driving thin film transistors may include a main driving thin film transistor corresponding to the main pixel and a sub driving thin film transistor corresponding to the sub-pixel. A gate of the main driving thin film transistor and agate of the sub-driving thin film transistor may be coupled to one of the first scan lines. A source of the main driving thin film transistor and a source of the sub driving thin film transistor may act as a charge input terminal of the pixel. A drain of the main driving thin film transistor may be a charge storage terminal of the main pixel, and the drain of the sub-driving thin film transistor may be a charge storage terminal of the sub-pixel.

Optionally, the gate of each of the charge sharing thin film transistors may be coupled to one of the second scan lines. The source of the charge sharing thin film transistor may be coupled to the charge storage terminal of the sub-pixel. The drain of the charge sharing thin film transistor may be a shared charge storage terminal of the sub-pixel.

Optionally, the driving thin film transistors may include a main driving thin film transistor corresponding to the main pixel and the sub driving thin film transistor corresponding to the sub-pixel. The gate of the main driving thin film transistor and the gate of the sub-driving thin film transistor may be coupled to one of the first scan lines. The drain of the main driving thin film transistor and the drain of the sub driving thin film transistor may act as the charge input terminal of the pixel. The source of the main driving thin film transistor may be a charge storage terminal of the main pixel, and the source of the sub-driving thin film transistor may be the charge storage terminal of the sub-pixel.

Optionally, the gate of each of the charge sharing thin film transistors may be coupled to one of the second scan lines. The source of the charge sharing thin film transistor may be coupled to the charge storage terminal of the sub-pixel. The drain of the charge sharing thin film transistor may be a shared charge storage terminal of the sub-pixel.

Optionally, the first substrate row driving circuit may include a plurality of first substrate row driving sub-circuits, and each of the first substrate row driving sub-circuits may be coupled to a corresponding one of the first scan lines. The second substrate row driving circuit may include a plurality of second substrate row driving sub-circuits, and each of the second substrate row driving sub-circuits may be coupled to the corresponding one of the second scan lines.

To achieve the above-described object, this application further provides a drive device including:

an active switch array including main driving thin film transistors, sub-driving thin film transistors, and charge sharing thin film transistors;

a scan line array including first scan lines and second scan lines, where the first scan lines are configured to independently drive the main driving thin film transistors and sub-driving thin film transistors, while the second scan lines are configured to independently drive the charge sharing thin film transistors;

a substrate row driving circuitry including a first substrate row driving circuit and a second substrate row driving circuit. The first substrate row driving circuit may be disposed on one side of the scan line array, while the second substrate row driving circuit may be disposed on the other side of the scan line array.

The first substrate row driving circuit may include a plurality of first substrate row driving sub-circuits with each of the first substrate row driving sub-circuits coupled to a corresponding one of the first scan lines and configured to independently drive the corresponding coupled first scan line.

The second substrate row driving circuit may include a plurality of second substrate row driving sub-circuits with each of the second substrate row driving sub-circuits coupled to a corresponding one of the second scan lines and configured to independently drive the corresponding coupled second scan line.

After the first substrate row driving sub-circuits drive the first scan lines, the second substrate row driving sub-circuits may then drive the second scan lines.

When the second substrate row driving sub-circuits are independently driving the second scan lines, a potential difference may occur between a main pixel and a sub-pixel in the display area corresponding to the active switch array.

To achieve the above-described object, this application further provides a display device that includes a liquid crystal panel, a backlight module, and the above-described drive device.

According to the technical solution proposed by this application, the substrate row driving circuitry includes a first substrate row driving circuit disposed on one side of the scan line array and a second substrate row driving circuit disposed on the other side of the scan line array. After the first substrate row driving circuit independently drives the first scan lines, the second substrate row driving circuit would then independently drive the second scan lines. Thus, when the second substrate row driving circuit is independently driving the second scan lines, a potential difference would generate between a main pixel and a sub-pixel of the display area corresponding to the active switch array. Because the first substrate row driving circuit and the second substrate row driving circuit are separately disposed at two ends of the pixel region and independent from each other, and drive and control different scan lines, different sides would drive different scan lines thus reducing the load on each scan line.

### BRIEF DESCRIPTION OF THE ACCOMPANYING DRAWINGS

To better illustrate the technical solutions according to the embodiments of this application or the prior art, the accompanying drawings required for the description of the embodiments herein or the prior art will now be briefly described. Apparently, the accompanying drawings in the following description show merely some embodiments of this application, and those of ordinary skill in the art will be able to obtain other drawings based on the arrangements shown in these drawings without making creative efforts, where in the drawings:

FIG. 1 is a block diagram of a drive device in accordance with an embodiment of this application.

FIG. 2 is a schematic diagram of the drive device illustrated in FIG. 1.

Implementations, functional features, and advantages of this application will now be described in further detail in connection with embodiments and the accompanying drawings.

### DETAILED DESCRIPTION OF ILLUSTRATED EMBODIMENTS

It will be appreciated that the embodiments described herein are merely illustrative of the application and are not intended to limit the application.

Technical solutions embodied in the embodiments of this application will now be clearly and comprehensively described in connection with the accompanying drawings intended for these embodiments. Apparently, the described embodiments are merely some but not all embodiments of this application. All other embodiments obtained by persons of ordinary skill in the art based on the embodiments of this application without making creative efforts shall all fall within the protection scope of this application.

It should be noted that, all directional indicators (such as “upper,” “lower,” “left,” “right,” “front,” “rear,” . . . ) in the embodiments of this application are merely used to explain the relative positions and movement or the like between various components under a specific posture (as shown in the drawings), and should the specific posture change, these directional indicators will also change accordingly.

As used herein, terms such as “first,” or “second,” are intended for illustrative purposes only and are not to be construed as indicating or implying their relative importance or implicitly indicating the number of the specified technical features. Thus, a feature defined by terms such as “first” or “second” may explicitly or implicitly includes at least one of such feature. Additionally, technical solutions of various embodiments may be combined with one another, but such combinations must be based on the achievability by those of ordinary skill in the art. Where a combination of technical solutions is found contradictory or unachievable, such a combination may be regarded as non-existent nor would it fall within the scope of protection of this application.

This application provides a drive device that can be applied to a display device. The display device can be a display panel such as a liquid crystal display (LCD). The LCD can be a Vertical Alignment (VA) panel, an In-Plane switching panel, or a Twisted Nematic (TN) panel. The display device may include a pixel region composed of a pixel array. Each pixel may include a main pixel and a sub-pixel. According to this solution, the distinction of the main pixel and sub-pixel is chiefly intended for the purpose of applying to the Low Color Shift design intended to reduce a color shift.

It should be noted that scan lines of a scan line array in the existing drive devices are divided into gate lines and sharing lines, and each scan line is driven by a GOA (Gate on Array) circuit. For example, the process of the gate lines and the sharing lines driving a TFT array to reduce the color shift can be as follows. In an Ath row of pixels enclosed by a gate line B and a sharing line C, the GOA circuit controls the gate line B to turn on thus charging the Ath row of pixels. Then after the gate line B is turned off, the sharing line C is turned on to control a potential difference to be generated within the the Ath row of pixels. After the sharing line C controls the potential difference to be generated within the Ath row of pixels, the sharing line C then acts as a gate line of the (A+1)th row of pixels to control a charging of the (A+1)th row of pixels, and so on. In the above solution, the sharing line can be understood as a common line. That means the GOA circuit needs to drive the sharing line to implement two different functions in succession. Therefore, the load on the scan lines that control the potential difference to generate between the driving TFTs (Thin Film Transistors) is large.

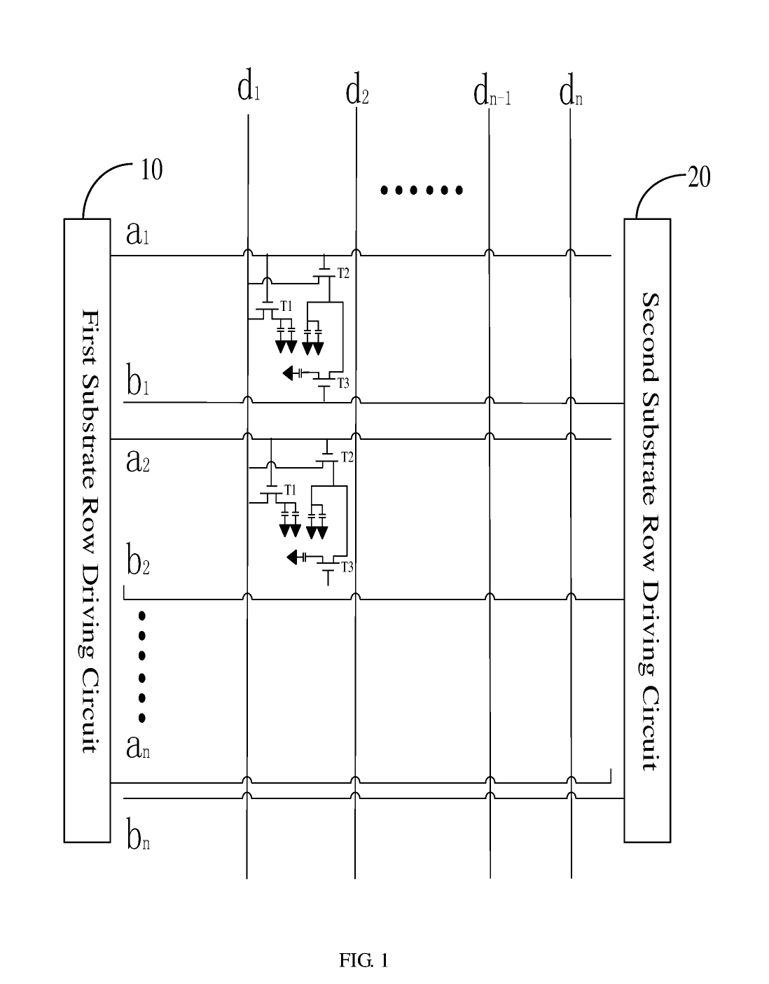

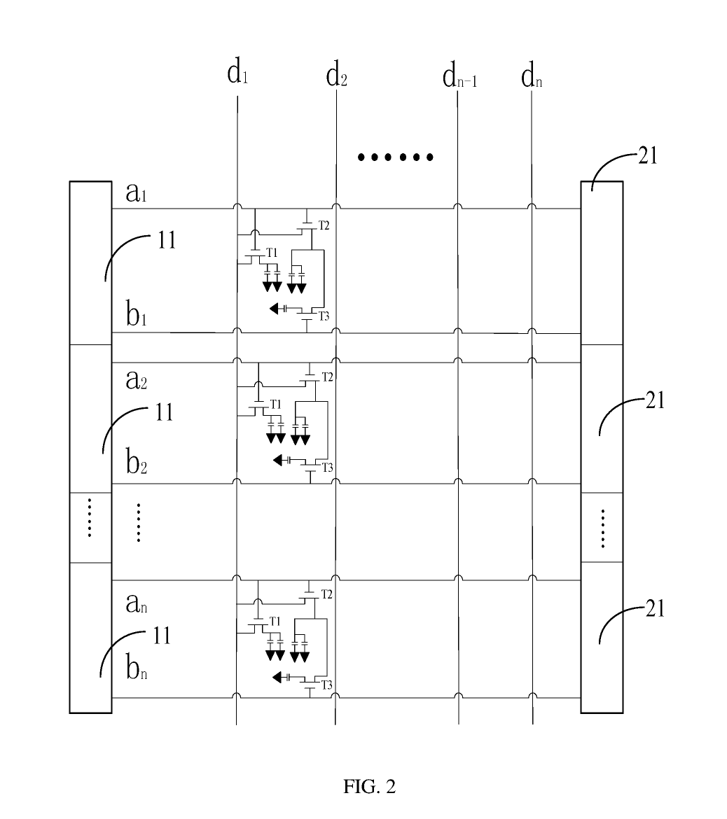

As illustrated in FIGS. 1 and 2, in an embodiment, the drive device includes: an active switch array (not shown) that includes driving TFTs and charge sharing TFTs (T3); a scan line array (not shown) that includes first scan lines aₙ(n=1,2, . . . ,n) and second scan lines bₙ(n=1,2, . . . ,n), where the first scan lines aₙ(n=1,2, . . . ,n) are configured to independently drive the driving TFTs while the second scan lines bₙ(n=1,2, . . . ,n) are configured to independently drive the charge sharing TFTs (T3); and a substrate row driving circuitry (not shown) including a first substrate row driving circuit 10 disposed on one side of the scan line array and configured to independently drive the first scan lines aₙ(n=1,2, . . . ,n), and a second substrate row driving circuit 20 disposed on the other side of the scan line array and configured to independently drive the second scan lines bₙ(n=1,2, . . . ,n).

After the first substrate row driving circuit 10 independently drives the first scan lines aₙ(n=1,2, . . . ,n), the second substrate row driving circuit 20 would then independently drive the second scan lines bₙ(n=1,2, . . . ,n). Thus, when the second substrate row driving circuit 20 is independently driving the second scan lines bₙ(n=1,2, . . . ,n), a potential difference would generate between a main pixel and a sub-pixel of the display area corresponding to the active switch array.

In this embodiment, the first substrate row driving circuit 10 and the second substrate row driving circuit 20 as configured are respectively disposed on two sides of the scan line array and respectively control different scan lines. For example, the scan lines may include first scan lines aₙ(n=1,2, . . . ,n) and second scan lines bₙ(n=1,2, . . . ,n), and the first substrate row driving circuit 10 may independently drive the first scan lines aₙ(n=1,2, . . . ,n) while the second substrate row driving circuit 20 may independently drive the second scan lines bₙ(n=1,2, . . . ,n). It should be noted that by “the first substrate row driving circuit 10 independently drives the first scan lines aₙ(n=1,2, . . . ,n)”, it can mean the first substrate row driving circuit 10 drives the first scan lines aₙ(n=1,2, . . . ,n) to turn on or off so as to control the turning on or off the driving TFTs. Likewise, by “the second substrate row driving circuit 20 independently drives the second scan lines bₙ(n=1,2, . . . ,n)”, it can mean that the second substrate row driving circuit 20 drives the second scan lines bₙ(n=1,2, . . . ,n) to turn on or off so as to control the turning on or off the charge sharing TFTs (T3).

The above-described active switch array may be a TFT array, while the substrate row driving circuitry may be an array substrate row driving circuit. Optionally, each of the above-described driving TFTs may include a main driving TFT (T1) corresponding to a main pixel and a sub-driving TFT (T2) corresponding to a sub-pixel. Thus, the first substrate row driving circuit 10 can drive the first scan lines aₙ(n=1,2, . . . ,n) to turn on or off in order to control the turning on or off of the main driving TFTs (T1) and the sub-driving TFTs (T2). As such, by controlling the main driving TFTs (T1) and the sub-driving TFTs (T2) to turn on, the main driving TFTs (T1) and the sub-driving TFTs (T2) can perform charge inputting operations.

For example, the implementation process of the drive device reducing the color shift can be as follows. After the first substrate row driving circuit 10 drives the first scan lines aₙ(n=1,2, . . . ,n), the second substrate row driving circuit then drives the second scan lines bₙ(n=1,2, . . . ,n) so as to generate a potential difference between the main pixel and the sub-pixel in the display area. As such, the liquid crystal in the liquid crystal layer of the display device would produce a tilt angle due to a change of the potential difference, thereby achieving the effect of reducing the color shift. Because the first substrate row driving circuit 10 and the second substrate row driving circuit 20 are respectively disposed on two sides of the second scan line array and respectively drive and control the first scan lines aₙ(n=1,2, . . . ,n) and the second scan lines bₙ(n=1,2, . . . ,n), the original sharing lines are divided into two parts. Therefore, the original load on the sharing lines is reduced; that is, the load on the scan lines in the scan line array is equalized. In addition, by disposing the first substrate row driving circuit 10 and the second substrate row driving circuit 20 at two opposite ends of the pixel region, a unilateral driving can be achieved, and it can facilitate the GOA circuit with the control over the scan line array and can also facilitate a precise arrangement.

In addition, the first scan lines aₙ(n=1,2, . . . ,n) may be disposed parallel to and alternately with the second scan lines bₙ(n=1,2, . . . ,n). This arrangement is in line with the arrangement of the scan line array thus maximum ensuring the number of pixels, while the loading times of adjacent scan lines can be the same theoretically thereby facilitating the detection.

The first substrate row driving circuit 10 may include a plurality of first substrate row driving sub-circuits 11. Each of the first substrate row driving sub-circuits 11 may be coupled to a corresponding one of the first scan lines aₙ(n=1,2, . . . ,n). The second substrate row driving circuit 20 may include a plurality of second substrate row driving sub-circuits 21. Each of the second substrate row driving sub-circuits 21 may be coupled to a corresponding one of the second scan lines bₙ(n=1,2, . . . ,n). The number of the first substrate row driving sub-circuits 11 can be the same as the number of the second substrate row driving sub-circuits 21. With the first substrate row driving circuit 10 composed of multiple first substrate row driving sub-circuits 11 and the second substrate row driving circuit 20 composed of multiple second substrate row driving sub-circuits 21 as well as the first scan line aₙ(n=1,2, . . . ,n) or second scan lines bₙ(n=1,2, . . . ,n) corresponding to each sub-circuit, an accurate control of the scan line array and the active switch array can be accomplished by the array substrate row driving circuit.

In combination with the above-described configuration, the drive device may include, in an embodiment for example: an active switch array that includes main driving TFTs (T1), sub-driving TFTs (T2), and charge sharing TFTs (T3); a scan line array that includes first scan lines aₙ(n=1,2, . . . ,n) and second scan lines bₙ(n=1,2, . . . ,n), where the first scan lines aₙ(n=1,2, . . . ,n) are configured to independently drive the main driving TFTs (T1) and sub-driving TFTs (T2) while the second scan lines bₙ(n=1,2, . . . ,n) are configured to independently drive the charge sharing TFTs (T3); and a substrate row driving circuitry including a first substrate row driving circuit 10 and a second substrate row driving circuit 20. The first substrate row driving circuit 10 may be disposed on one side of the scan line array, while the second substrate row driving circuit 20 may be disposed on the other side of the scan line array, where the first substrate row driving circuit 10 may include a plurality of first substrate row driving sub-circuits 11 with each of the first substrate row driving sub-circuits 11 coupled to a corresponding one of the first scan lines aₙ(n=1,2, . . . ,n) and configured to independently drive the corresponding coupled first scan line aₙ(n=1,2, . . . ,n); the second substrate row driving circuit 20 may include a plurality of second substrate row driving sub-circuits 21 with each of the second substrate row driving sub-circuits 21 coupled to a corresponding one of the second scan lines bₙ(n=1,2, . . . ,n) and configured to independently drive the corresponding coupled second scan line bₙ(n=1,2, . . . ,n).

After the first substrate row driving sub-circuits 11 drive the first scan lines aₙ(n=1,2, . . . ,n), the second substrate row driving sub-circuits 21 may then drive the second scan lines bₙ(n=1,2, . . . ,n).

When the second substrate row driving sub-circuits 21 are independently driving the second scan lines bₙ(n=1,2, . . . ,n), a potential difference may occur between a main pixel and a sub-pixel in the display area corresponding to the active switch array.

Optionally, in the above-described drive device, the circuit connection structure of the active switch array may be set according to actual needs. For example, the gate of the main driving TFT (T1) and the gate of the sub-driving TFT (T2) may be coupled to the first scan lines aₙ(n=1,2, . . . ,n), while the source of the main driving TFT (T1) and the source of the sub-driving TFT (T2) may act as a charge input terminal of the pixel. The drain of the main driving TFT (T1) may be a charge storage terminal of the main pixel while the drain of the sub-driving TFT (T2) may be a charge storage terminal of the sub-pixel. The gate of each of the charge sharing TFTs (T3) maybe coupled to one of the second scan lines bₙ(n=1,2, . . . ,n). The source of the charge sharing TFT (T3) may be coupled to the charge storage terminal of the sub-pixel. The drain of the charge sharing TFT (T3) may be a shared charge storage terminal of the sub-pixel.

Alternatively the connecting orientations of the drain and source of a thin film transistor can also be exchanged. That is, the gate of the main driving TFT (T1) and the gate of the sub-driving TFT (T2) may be coupled to the first scan line^{a}^{ₙ}^{(n=1,2, . . . ,n)}, while the drain of the main driving TFT (T1) and the drain of the sub-driving TFT (T2) may act as a charge input terminal of the pixel. The source of the main driving TFT (T1) may be a charge storage terminal of the main pixel while the source of the sub-driving TFT (T2) may be a charge storage terminal of the sub-pixel. The gate of each of the charge sharing TFTs (T3) may be coupled to the second scan lines bₙ(n=1,2, . . . ,n). The drain of the charge sharing TFT (T3) may be coupled to the charge storage terminal of the sub-pixel. The source of the charge sharing TFT (T3) may be a shared charge storage terminal of the sub-pixel.

When the first substrate row driving circuit 10 drives the first scan lines aₙ(n=1,2, . . . ,n), the gate of the driving thin film transistor corresponding to a main pixel and a sub-pixel would be turned on, and so charges would be input through the charge input terminal of the main pixel and the charge input terminal of the sub-pixel. Furthermore, the charges will be stored at the charge storage terminal of the main pixel and the charge storage terminal of the sub-pixel, respectively. When the second substrate row driving circuit 20 is driving the second scan lines bₙ(n=1,2, . . . ,n), the gate of the charge sharing TFT (T3) of the sub-pixel would be turned on, and the charges in the charge storage terminal of the sub-pixel would flow to the shared charge storage terminal of the sub-pixel. Therefore, a potential difference would be generated between the sub-pixel and the main pixel, thereby changing the tilt angle of the liquid crystal. With the circuit layout formed by the main driving TFTs (T1), the sub-driving TFTs (T2), as well as the charge sharing TFTs (T3), thus a complete hardware configuration is provided for a low color shift design of the driving panel.

This application further provides a display device that includes a display panel, a backlight module, and a drive device; for a configuration of the drive device, referencing to the embodiments described supra. It should be noted that, because the display device according to this embodiment adopts the technical solution of the above-described drive device, the display device would possess all the advantages of the above-described drive device.

The foregoing description merely illustrates some possible embodiments of the application and therefore is not intended as limiting the patentable scope of the application. Any equivalent configurational or flow transformations that are made taking advantage of the application and that are used directly or indirectly in other related technical fields shall all fall in the patentable scope of protection of this application.

What is claimed is:

1. A drive device, comprising:
an active switch array, comprising driving thin film transistors and charge sharing thin film transistors;
a scan line array, comprising first scan lines configured to independently drive the driving thin film transistors and second scan lines configured to independently drive the charge sharing thin film transistors; and
a substrate row driving circuitry comprising:
a first substrate row driving circuit disposed on one side of the scan line array and configured to independently drive the first scan lines; and
a second substrate row driving circuit disposed on the other side of the scan line array and configured to independently drive the second scan lines;
wherein after the first substrate row driving circuit independently drives the first scan lines, the second substrate row driving circuit drives the second scan lines;
when the second substrate row driving circuit is independently driving the second scan lines, a potential difference is generated between a main pixel and a sub-pixel in a display area corresponding to the active switch array.

2. The drive device of claim 1, wherein the first substrate row driving circuit comprises a plurality of first substrate row driving sub-circuits, and each of the first substrate row driving sub-circuits is coupled to one of the first scan lines; the second substrate row driving circuit comprises a plurality of second substrate row driving sub-circuits, and each of the second substrate row driving sub-circuits is coupled to one of the second scan lines.

3. The drive device of claim 1, wherein the first substrate row driving circuit is configured to drive the first scan lines to turn on or off in order to control the turning on or off of the driving thin film transistors.

4. The drive device of claim 3, wherein the first substrate row driving circuit comprises a plurality of first substrate row driving sub-circuits, and each of the first substrate row driving sub-circuits is coupled to one of the first scan lines; the second substrate row driving circuit comprises a plurality of second substrate row driving sub-circuits, and each of the second substrate row driving sub-circuits is coupled to one of the second scan lines.

5. The drive device of claim 3, wherein the second substrate row driving circuit is configured to drive the second scan lines to turn on or off in order to control the turning on or off of the charge sharing thin film transistors.

6. The drive device of claim 5, wherein each of the driving thin film transistors comprises a main driving thin film transistor corresponding to the main pixel and a sub driving thin film transistor corresponding to the sub-pixel, wherein a gate of the main driving thin film transistor and a gate of the sub driving thin film transistor are coupled to the first scan lines, a source of the main driving thin film transistor and a source of the sub driving thin film transistor act as a charge input terminal of a pixel, a drain of the main driving thin film transistor is a charge storage terminal of the main pixel, and a drain of the sub driving thin film transistor is a charge storage terminal of the sub-pixel.

7. The drive device of claim 6, wherein a gate of the each of the charge sharing thin film transistors is coupled to the second scan lines, a source of the charge sharing thin film transistor is coupled to the charge storage terminal of the sub-pixel, and a drain of the charge sharing thin film transistor acts as a shared charge storage terminal of the sub-pixel.

8. The drive device of claim 5, wherein the driving thin film transistors comprises a main driving thin film transistor corresponding to the main pixel and a sub driving thin film transistor corresponding to the sub-pixel, wherein a gate of the main driving thin film transistor and a gate of the sub driving thin film transistor are respectively coupled to the first scan lines, a drain of the main driving thin film transistor and a drain of the sub driving thin film transistor act as a charge input terminal of the pixel, a source of the main driving thin film transistor is a charge storage terminal of the main pixel, and a source of the sub driving thin film transistor is a charge storage terminal of the sub-pixel.

9. The drive device of claim 8, wherein a gate of each of the charge sharing thin film transistors is coupled to the second scan lines, a drain of the charge sharing thin film transistor is coupled to the charge storage terminal of the sub-pixel, and a source of the charge sharing thin film transistor acts as a shared charge storage terminal of the sub-pixel.

10. A drive device, comprising:
an active switch array, comprising main driving thin film transistors, sub driving thin film transistors, and charge sharing thin film transistors;
a scan line array, comprising first scan lines configured to independently drive the main driving thin film transistors and second scan lines configured to independently drive the charge sharing thin film transistors;
a substrate row driving circuitry, comprising a first substrate row driving circuit disposed on one side of the scan line array, and a second substrate row driving circuit disposed on the other side of the scan line array; wherein the first substrate row driving circuit comprises a plurality of first substrate row driving sub-circuits with each of the first substrate row driving sub-circuits coupled to a corresponding one of the first scan lines and configured to independently drive the corresponding coupled first scan line, and the second substrate row driving circuit comprises a plurality of second substrate row driving sub-circuits with each of the second substrate row driving sub-circuits coupled to a corresponding one of the second scan lines and configured to independently drive the corresponding coupled second scan line; and wherein after the first substrate row driving sub-circuits drive the first scan lines, the second substrate row driving sub-circuits drive the second scan lines, and when the second substrate row driving sub-circuits are independently driving the second scan lines, a potential difference is generated between a main pixel and a sub-pixel in a display area corresponding to the active switch array.

11. The drive device of claim 10, wherein the first substrate row driving circuit is configured to drive the first scan lines to turn on or off in order to control the turning on or off of the driving thin film transistors.

12. The drive device of claim 11, wherein the second substrate row driving circuit is configured to drive the second scan lines to turn on or off in order to control the turning on or off of the charge sharing thin film transistors.

13. The drive device of claim 12, wherein a gate of the main driving thin film transistor and a gate of the sub driving thin film transistor are coupled to a first scan line, a source of the main driving thin film transistor and a source of the sub driving thin film transistor act as a charge input terminal of the pixel, a drain of the main driving thin film transistor is a charge storage terminal of the main pixel, and a drain of the sub driving thin film transistor is a charge storage terminal of the sub-pixel.

14. The drive device of claim 13, wherein a gate of each of the charge sharing thin film transistors is coupled to the second scan lines, a source of the charge sharing thin film transistor is coupled to the charge storage terminal of the sub-pixel, and a drain of the charge sharing thin film transistor acts as a shared charge storage terminal of the sub-pixel.

15. The drive device of claim 12, wherein a gate of the main driving thin film transistor and a gate of the sub driving thin film transistor are coupled to a first scan line, a drain of the main driving thin film transistor and a drain of the sub driving thin film transistor act as a charge input terminal of the pixel, a source of the main driving thin film transistor is a charge storage terminal of the main pixel, and a source of the sub driving thin film transistor is a charge storage terminal of the sub-pixel.

16. The drive device of claim 15, wherein a gate of each of the charge sharing thin film transistors is coupled to the second scan lines, a drain of the charge sharing thin film transistor is coupled to the charge storage terminal of the sub-pixel, and a source of the charge sharing thin film transistor acts as a shared charge storage terminal of the sub-pixel.

17. A display device, comprising a display panel, a backlight module, and a drive device, the drive device comprising:
an active switch array, comprising driving thin film transistors and charge sharing thin film transistors;
a scan line array, comprising first scan lines configured to independently drive the driving thin film transistors and second scan lines configured to independently drive the charge sharing thin film transistors; and
a substrate row driving circuitry comprising:
a first substrate row driving circuit disposed on one side of the scan line array and configured to independently drive the first scan lines; and
a second substrate row driving circuit disposed on the other side of the scan line array and configured to independently drive the second scan lines;
wherein after the first substrate row driving circuit independently drives the first scan lines, the second substrate row driving circuit drives the second scan lines;
when the second substrate row driving circuit is independently driving the second scan lines, a potential difference is generated between a main pixel and a sub-pixel in a display area corresponding to the active switch array.

18. The display device of claim 17, wherein the first substrate row driving circuit comprises a plurality of first substrate row driving sub-circuits, and each of the first substrate row driving sub-circuits is coupled to one of the first scan lines; the second substrate row driving circuit comprises a plurality of second substrate row driving sub-circuits, and each of the second substrate row driving sub-circuits is coupled to one of the second scan lines.

19. The display device of claim 18, wherein the first substrate row driving circuit is configured to drive the first scan lines to turn on or off in order to control the turning on or off of the driving thin film transistors.

20. The display device of claim 19, wherein the second substrate row driving circuit is configured to drive the second scan lines to turn on or off in order to control the turning on or off of the charge sharing thin film transistors.
